(19) United States
(12) Patent Application Publication
(10) Pub. No.: US 2014/0361847 A1
(43) Pub. Date: Dec. 11, 2014

(54) LOW LOSS MULTIPLE OUTPUT SWITCH WITH INTEGRATED DISTRIBUTED ATTENUATION

(71) Applicant: QUALCOMM Incorporated, San Diego, CA (US)

(72) Inventors: Jeremy Mark GOLDBLATT, Encinitas, CA (US); Haigang FENG, San Diego, CA (US)

(73) Assignee: QUALCOMM Incorporated, San Diego, CA (US)

(21) Appl. No.: 13/910,907

(22) Filed: Jun. 5, 2013

(51) Int. Cl. H01P 1/10; H03H 7/38

(52) U.S. Cl. CPC H03H 7/38
USPC 333/101; 333/130

(57) ABSTRACT

A low loss multiple output switch with integrated distributed attenuation is disclosed. In an exemplary embodiment, an apparatus includes a switchable shunt network having an input terminal and a plurality of network output terminals, the switchable shunt network comprising selectable signal paths that connect the input terminal to the network output terminals. The apparatus also includes selectable shunt impedances connected to the selectable signal paths to adjust parasitic loading on the selectable signal paths.

### BACKGROUND

1. Field

The present application relates generally to the operation and design of analog front ends, and more particularly, to the operation and design of switches having multiple outputs.

2. Background

In a single transmitter capable of transmitting over multiple frequency bands, the transmitter's front end components should be designed for the different frequency bands in order to achieve good performance and efficiency. Therefore, it is desirable to have an on-die switch that supports one input and multiple outputs with low insertion loss and high reverse isolation. Furthermore, a signal attenuator may also be desired for each output to provide gain and optimal output noise control.

Typically, existing multiband transmitters utilize an attenuator followed by one or more switches to attenuate and direct transmit signals to the appropriate power amplifier for transmission. Unfortunately, this configuration results in several undesirable effects. For example, the attenuator provides extra insertion loss even when operating in a “no attenuation” mode. This insertion loss is due to all shunt elements of the attenuator being tied to the main signal path, thereby causing parasitic loading in addition to the loss caused by the switches. Furthermore, since the attenuator has high parasitic loss due to the connection of the shunt elements to the main signal path, this loss may also impact the design of a driver amplifier that feeds the attenuator. Thus, for a switch having a high output port count, conventional designs may not be optimal.

Therefore, it would be desirable to have a multiport switch that provides the desired switching and attenuation while providing low insertion loss and good port-to-port isolation.

### BRIEF DESCRIPTION OF THE DRAWINGS

The foregoing aspects described herein will become more readily apparent by reference to the following description when taken in conjunction with the accompanying drawings wherein:

FIG. 1 shows a transmitter front end comprising an exemplary embodiment of a multiport switch with integrated distributed attenuation for use in a wireless device;

FIG. 2 shows a detailed exemplary embodiment of a multiport switch with distributed integrated attenuation;

FIG. 3 shows a detailed exemplary embodiment of a multiport switch with distributed integrated attenuation;

FIG. 4 shows an exemplary embodiment of a ladder network that comprises an exemplary embodiment of a switchable shunt network; and

FIG. 5 shows an exemplary embodiment of a switchable shunt network apparatus.

### DETAILED DESCRIPTION

The detailed description set forth below in connection with the appended drawings is intended as a description of exemplary embodiments of the invention and is not intended to represent the only embodiments in which the invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein.

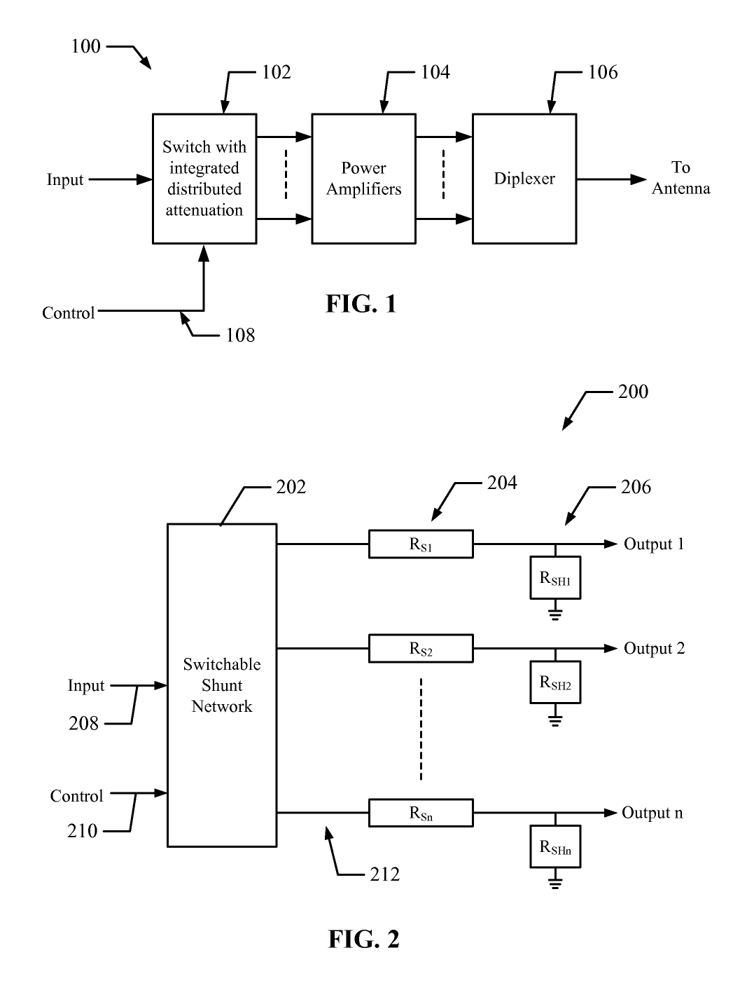

FIG. 1 shows a transmitter front end 100 comprising an exemplary embodiment of a multiport switch 102 with integrated distributed attenuation for use in a wireless device. The front end 100 also comprises power amplifiers 104 and a diplexer 106.

The switch 102 with integrated distributed attenuation receives an input signal from a driver amplifier or other device in the transmit chain. The switch 102 also receives a control signal 108 from a baseband processor or other entity at the wireless device. The switch 102 comprises a plurality of internal switches that are opened and closed based on the control signal 108 so that the input signal flows through the enabled internal switches to a corresponding power amplifier 104. The outputs of the power amplifiers 104 are input to a diplexer 106 that couples the power amplifier outputs to an antenna.

The switch 102 comprises distributed integrated attenuation so that based on the control signal 108; a switch path having a selected amount of attenuation and parasitic loss can be selected. In various exemplary embodiments, the integrated attenuation is distributed throughout the switch 102 so that parasitic loss can be reduced. This improves the insertion loss resulting from the switch 102 and the reduced parasitic loss minimizes the impact to a driver amplifier that feeds the switch, which makes a single driver amplifier design for a multi-band transmitter achievable. A more detail description of the switch 102 with integrated distributed attenuation is provided below.

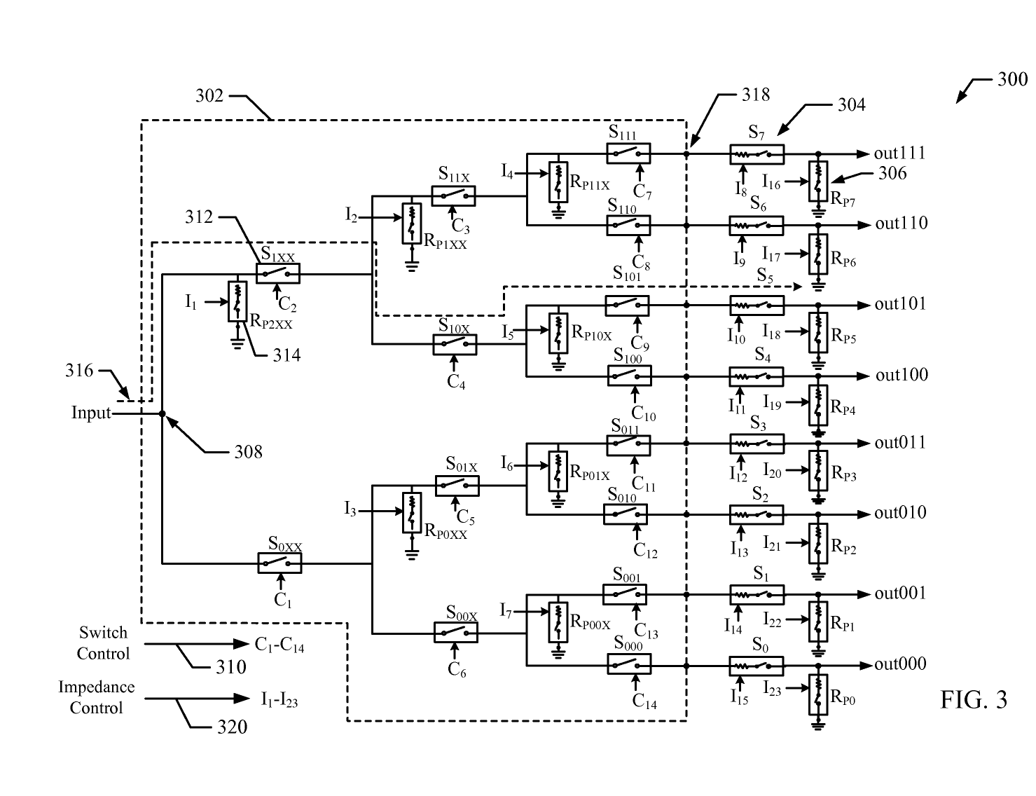

FIG. 2 shows a detailed exemplary embodiment of a multiport switch 200 with distributed integrated attenuation. For example, the switch 200 is suitable for use as the switch 102 shown in FIG. 1. The switch 200 comprises a switchable shunt network 202, series resistors 204 and shunt output resistors 206. The switchable shunt network 202 receives an input signal 208 and a control signal 210. The control signal 210 opens and closes internal switches of the switchable shunt network 202 to enable the input signal to flow to one of (N) ports 212 of the switchable shunt network 202. In various exemplary embodiments, the multiport switch 200 can support any number of the ports 212 and associated outputs (Outputₙ). Each port 212 is connected to a corresponding series resistor (R_{S1}-R_{Sn}) 204, which provides corresponding output signals (Output 1-Output n). Additional shunt resistors (R_{SH1}-R_{SHn}) 206 are also coupled to their respective outputs and corresponding series resistors (R_{S1}-R_{Sn}) 204. In this exemplary embodiment, the switch 200 is configured to form a PI attenuator to provide attenuation to the input signal to form the output signals (Output 1-Output n). It should be noted that other attenuator configurations, such as T or L shaped attenuators can also be formed. Accordingly, the switch 200 provides for distributed attenuation and port isolation as described in more detail below.

FIG. 3 shows a detailed exemplary embodiment of a multiport switch 300 with distributed integrated attenuation. For example, the switch 300 is suitable for use as the switch 200 shown in FIG. 2. The switch 300 comprises a switchable shunt network 302, switchable series resistors (S₀-S₇) (shown generally at 304) and switchable shunt resistors (R_{PX}) shown generally at 306 that are shunted to signal ground.

The switchable shunt network 302 receives an input signal at an input terminal 308, switch control signals (C₁-C₁₄) 310, and impedance control signals (I₁-I₂₃) 320. The switchable shunt network 302 comprises internal switches Sxxx (such as switch 312) and internal shunt elements R_{PXXX} (such as shunt element 314) that are shunted to signal ground. The switches S_{XXX} are configured in a fan-out configuration where the input terminal 308 is connected to network output terminals 318 by selectable signal paths. For example, the input terminal 308 is connected to the inputs of switches S0xx and S1xx and each output from these switches is further connected to the input of two additional switches. Thus, the output terminal of a particular internal switch is connected to the input terminals of two additional internal switches. The operation of the internal switches Sxxx is controlled by the control signal 310, so that based on the particular switch settings enabled by the control signal 310; a signal path from the input terminal 308 to any network output terminal 318 can be established (i.e., selectively enabled).

The shunt elements (Rpxxx) comprise impedances (i.e., resistors, capacitors, and/or inductors) coupled to a corresponding switch to form a selectable impedance. The shunt elements are distributed throughout the switchable shunt network 302 so that a shunt element is connected to a node that is connected to the inputs terminals of two internal switches. The shunt elements comprise additional switches that are configured to open or close based on the impedance control 320. When, for example, an additional switch is closed, the corresponding impedance shunt is enabled, and if open, then disabled.

The network output terminals 318 are connected to the input terminals of switchable series resistances (Sx) 304. The output terminals of the switchable series resistances (Sx) 304 form switch outputs (out000-out111). Switchable shunt resistances (Rpx) 306 are also connected to the switch output terminals. In this exemplary embodiment, the internal shunt elements Rpxxx in combination with the series resistances (Sx) and shunt resistances (Rpx) form Pi attenuators so that the parasitic load of the internal shunt elements is distributed throughout the switchable shunt network 302. By distributing the parasitic load throughout the switchable shunt network 302, parasitic loading for any particular signal path through the switchable shunt network 302 is adjustable (i.e., increased, reduced or minimized) resulting in improved power efficiency while providing the required port to port isolation. It should be noted that it is also possible to configure the switch 300 to form distributed T shape and L shape attenuators.

For example, assuming a signal path 316 from the input terminal 308 to port (out101) is to be enabled. The switches S1xx, S10x, S101, and S₅ are closed by the switch control signals 310 and the impedance control signals 320. The shunt elements Rp2xx, Rp1xx, Rp10x, and R_{P5} are enabled by the impedance control signals 320. As a result, the impedance on the left side of the series impedance S₅ is the parallel combination of the shunt elements Rp2xx, Rp1xx, and Rp10x thereby providing a low impendence formed from the parallel combination of these elements. In a case where even lower impedance is needed on the left side of series resistor S₅, the switches S0xx, S00X and S01X could be turned on to add additional parallel shunt elements Rp0xx, Rp00x, Rp01x to the parallel impedance combination. For example, if the impedances of all the internal shunts of the shunt network 302 are set to 600 ohms, then the parallel combination of the enabled impedances will determined the impedance on the left side of the series impedance S₅. Accordingly, a variety of parallel combinations can be enabled to set the shunt impedance on the left side of the series impedance S₅ by controlling the internal switches 312 and shunt elements 314 and therefore allowing adjustment of the parasitic loading associated with selected signal paths. It should also be noted that the impedances shown in the multiport switch 300 can comprise any type of component such as resistors, capacitors, inductors or any other type of component. Furthermore, the switches shown in the multiport switch 300 can comprise any type of switching component, such as mechanical or semiconductor switches.

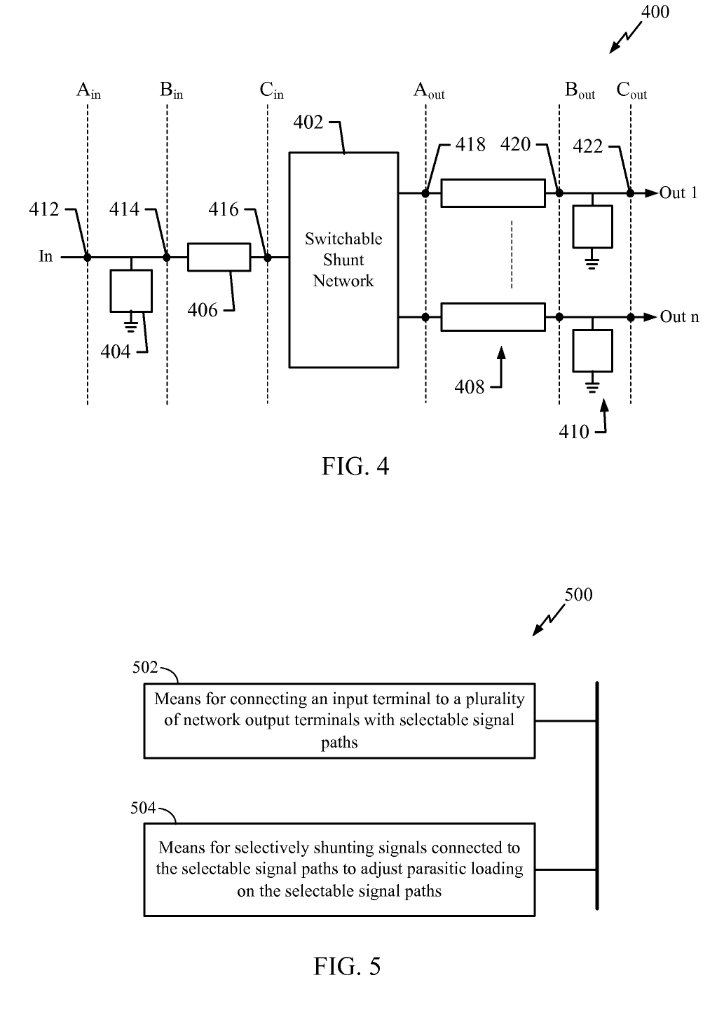

FIG. 4 shows an exemplary embodiment of a ladder network 400 that comprises an exemplary embodiment of a switchable shunt network 402. For example, in an exemplary embodiment, the switchable shunt network 402 comprises the switchable shunt network 302 shown in FIG. 3.

The ladder network 400 illustrates how the switchable shunt network 402 may be utilized in a variety of configurations to provide a low loss switch with distributed attenuation. The ladder network 400 comprises the switchable shunt network 402, shunt connected impedance 404, series connected impedance 406, series connected impedances 408 and shunt connected impedances 410. A plurality of input nodes and output nodes are defined. The input nodes include nodes 412, 414, and 416, and will be referred to as Aᵢₙ, Bᵢₙ and Cᵢₙ, respectively. The output nodes comprise nodes 418, 420 and 422, and will be referred to as Aₒᵤₜ, Bₒᵤₜ, and Cₒᵤₜ, respectively. It should be noted that terminal 416 represents the input terminal to the switchable shunt network 402 and the terminals 418 represent the network output terminals of the switchable shunt network 402.

A variety of attenuator types can be formed from the ladder network 400 using the input and output nodes. For example, by using Cᵢₙ as an input node and using Cₒᵤₜ as output nodes, the switchable shunt network 402 can be used to form a Pi shape attenuator. For example, such an attenuator is also illustrated in FIG. 2 and FIG. 3. A Pi shape attenuator can also be formed using Aᵢₙ as the input node and Aₒᵤₜ as the output nodes.

A T shape attenuator can be formed by using Bᵢₙ as the input node and Bₒᵤₜ as the output nodes. Furthermore, an L shape attenuator can be formed by using Bᵢₙ as the input node and Aₒᵤₜ as the output nodes.

Accordingly, various exemplary embodiments of the switchable shunt network 402 can be used to form a variety of attenuator shapes to provide a low loss switch with distributed attenuation, thereby reducing (or adjusting) parasitic loading on the selected switch paths. For example, the following attenuation configurations can be formed using the switchable shunt network 402.
1. Series in and shunt out
2. Shunt in and shunt out
3. Shunt in and series out
4. Series in and series out

FIG. 5 shows an exemplary embodiment of a switchable shunt network apparatus 500. For example, the apparatus 500 is suitable for use as the switchable shunt network 302 shown in FIG. 3. In an aspect, the apparatus 500 is implemented by one or more modules configured to provide the functions as described herein. For example, in an aspect, each module comprises hardware and/or hardware executing software.

The apparatus 500 comprises a first module comprising means (502) for connecting an input terminal to a plurality of network output terminals with selectable signal paths, which in an aspect comprises switchable shunt network 302.

The apparatus 500 comprises a second module comprising means (504) for selectively shunting signals connected to the selectable signal paths to adjust parasitic loading on the selectable signal paths, which in an aspect comprises the shunt impedances 314.

Those of skill in the art would understand that information and signals may be represented or processed using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof It is further noted that transistor types and technologies may be substituted, rearranged or otherwise modified to achieve the same results. For example, circuits shown utilizing PMOS transistors may be modified to use NMOS transistors and vice versa. Thus, the amplifiers disclosed herein may be realized using a variety of transistor types and technologies and are not limited to those transistor types and technologies illustrated in the Drawings. For example, transistors types such as BJT, GaAs, MOSFET or any other transistor technology may be used.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both non-transitory computer storage media and communication media including any medium that facilitates transfer of a computer program from one place to another. A non-transitory storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the invention is not intended to be limited to the exemplary embodiments shown herein but is to be accorded the widest scope consistent with the principles and novel features disclosed herein.

What is claimed is:

1. An apparatus comprising:
a switchable shunt network having an input terminal and a plurality of network output terminals, the switchable shunt network comprising selectable signal paths that connect the input terminal to the network output terminals; and
selectable shunt impedances connected to the selectable signal paths to adjust parasitic loading on the selectable signal paths.

2. The apparatus of claim 1, the switchable shunt network comprising a plurality of switches connected in a fan-out configuration and operable to connect the input terminal to the plurality of network output terminals, and wherein the selectable shunt impedances are connected to nodes that are common to inputs of two switches.

3. The apparatus of claim 2, the fan-out configuration is configured to provide at least four network output terminals.

4. The apparatus of claim 1, the selectable shunt impedances comprise a resistor connected in series with a switch.

5. The apparatus of claim 1, further comprising:
a first group of selectable impedances connected in series between the network output terminals and attenuator output terminals; and
a second group of selectable shunt impedances connected to the attenuator output terminals.

6. The apparatus of claim 5, the apparatus configured to form a Pi shaped attenuator.

7. The apparatus of claim 1, further comprising:
a first impedance connected in series with the input terminal; and
a first group of selectable impedances connected in series between the network output terminals and attenuator output terminals.

8. The apparatus of claim 7, the apparatus configured to form a T shaped attenuator.

9. The apparatus of claim 1, further comprising:
a first group of selectable impedances connected in series between the network output terminals and attenuator output terminals.

10. The apparatus of claim 9, the apparatus configured to form an L shaped attenuator.

11. An apparatus comprising:
means for connecting an input terminal to a plurality of network output terminals with selectable signal paths; and
means for selectively shunting signals connected to the selectable signal paths to adjust parasitic loading on the selectable signal paths.

12. The apparatus of claim 11, the means for connecting comprising a plurality of switches connected in a fan-out configuration and operable to connect the input terminal to the plurality of network output terminals, and wherein the means for shunting signals are connected to nodes that are common to inputs of two switches.

13. The apparatus of claim 12, the fan-out configuration is configured to provide at least four network output terminals.

14. The apparatus of claim 11, the means for selectively shunting signals comprise a resistor connected in series with a switch.

15. The apparatus of claim 11, further comprising:
a first group of selectable impedances connected in series between the network output terminals and attenuator output terminals; and
a second group of selectable shunt impedances connected to the attenuator output terminals.

16. The apparatus of claim 15, the apparatus configured to form a Pi shaped attenuator.

17. The apparatus of claim 11, further comprising:
a first impedance connected in series with the input terminal; and
a first group of selectable impedances connected in series between the network output terminals and attenuator output terminals.

18. The apparatus of claim 17, the apparatus configured to form a T shaped attenuator.

19. The apparatus of claim 11, further comprising:
a first group of selectable impedances connected in series between the network output terminals and attenuator output terminals.

20. The apparatus of claim 19, the apparatus configured to form an L shaped attenuator.
